(19) United States
(12) Patent Application Publication
(10) Pub. No.: US 2024/0361360 A1
(43) Pub. Date: Oct. 31, 2024

(54) ALTERNATING CURRENT SENSING APPARATUS

(71) Applicant: GM Global Technology Operations LLC, Detroit, MI (US)

(72) Inventors: Muhammad Hussain Alvi, Troy, MI (US); Suresh Gopalakrishnan, Troy, MI (US); Chunhao J. Lee, Troy, MI (US); Dongxu Li, Troy, MI (US)

(21) Appl. No.: 18/306,333

(22) Filed: Apr. 25, 2023

(51) Int. Cl. G01R 15/20; G01R 19/00; G01R 19/10

(52) U.S. Cl. CPC G01R 15/207; G01R 19/0092; G01R 19/10

(57) ABSTRACT

A current sensing apparatus includes a planar current conductor with a current shaping section, designed to carry an alternating current (AC) current with a maximum frequency. The current shaping section of the conductor consists of a pair of adjacent legs separated by a slot, which shapes the AC current to flow around the slot in opposite directions. The legs of the current conductor have a width no greater than twice the skin depth of the AC current at a frequency of at least half of the maximum frequency. The apparatus also includes a differential current sensor that measures the directional components of the AC current on opposite sides of the slot. This configuration allows for accurate current sensing while minimizing the effect of the skin effect at high frequencies, making it suitable for use in various applications where a broad range of fundamental frequencies are expected.

### INTRODUCTION

The subject disclosure relates to electric current conduction and sensing. More particularly, the subject disclosure relates to bus bar current conduction and sensing of phase currents in a multi-phase electric machine system.

High-voltage, high-current, multi-phase electric machine systems may be employed in industrial and transportation applications, for example. Alternating current (AC) phase currents may be conducted between a power inverter and phase windings of an electric machine. Cored current sensing of phase currents is practiced to provide phase current information for use in system control and diagnostics. However, cored sensing may come with certain volumetric and mass penalties as well as linearity, bandwidth and hysteretic issues due to core performance and saturation characteristics. Coreless current sensing may be undesirably affected by cross-coupled (superposed) fields from proximate conductors such as found in multi-phase power distribution between a power inverter and a multi-phase electric machine, particularly with highly integrated systems as may be practiced in automotive applications. Coreless sensing may also be sensitive to frequency induced phenomena such as conductor skin effect which may result in significant non-linear performance over wide ranges of fundamental operating frequencies as are characteristic with multi-phase electric machine systems used for vehicle propulsion.

### SUMMARY

In one exemplary embodiment, a current sensing apparatus may include a first planar current conductor carrying an alternating current (AC) current that is variable up to a predetermined maximum frequency, a current shaping section of the first planar current conductor including a pair of adjacent legs separated by a slot, the current shaping section configured to shape the AC current to flow around the slot such that the AC current has parallel directional components running parallel to the slot on opposite sides of the slot that are in opposite directions, each leg having width that is no greater than twice a skin depth of the AC current at not less than one-half of the predetermined maximum frequency, a differential current sensor sensing the parallel directional components of the AC current on opposite sides of the slot.

In addition to one or more of the features described herein, each leg may have width that is no greater than twice the skin depth of the AC current at not less than the predetermined maximum frequency.

In addition to one or more of the features described herein, each leg may be defined by a respective first conductor edge and a respective second conductor edge, the first conductor edge and the second conductor edge of each leg overlapping by no less than twice the skin depth of the AC current at not less than one-half of the predetermined maximum frequency.

In addition to one or more of the features described herein, each leg may be defined by a respective first conductor edge and a respective second conductor edge, the first conductor edge and the second conductor edge of each leg overlapping by no less than twice the skin depth of the AC current at the predetermined maximum frequency.

In addition to one or more of the features described herein, each leg may be defined by a respective first conductor edge and a respective second conductor edge, the first conductor edge and the second conductor edge of each leg overlapping by no less than twice the skin depth of the AC current at not less than one-half of the predetermined maximum frequency.

In addition to one or more of the features described herein, the current shaping section may be intermediate a first terminal section and a second terminal section, the first terminal section being oriented in a first orientation and the second terminal section being oriented in a second orientation.

In addition to one or more of the features described herein, the first orientation and the second orientation may be the same.

In addition to one or more of the features described herein, the first orientation and the second orientation may be perpendicular.

In addition to one or more of the features described herein, the first orientation of the first terminal section may be perpendicular to the parallel directional components of the AC current on opposite sides of the slot of the current shaping section.

In addition to one or more of the features described herein, the apparatus may further include a second planar current conductor, wherein the first orientations of each respective first terminal section may be perpendicular to the parallel directional components of the AC current on opposite sides of the slots of the respective current shaping sections, the first and second planar current conductors being coplanar and adjacent such that the first orientations of each respective first terminal section are parallel to each other and the second orientations of each respective second terminal section are parallel to each other, wherein the first terminal sections are separated by a distance L and the second terminal sections are separated by a distance T that is greater than the distance L.

In addition to one or more of the features described herein, each leg may be defined by a respective first conductor edge and a respective second conductor edge, wherein at least one of the respective first conductor edges and second conductor edges may be in contact with a thermally conductive electrical insulator.

In addition to one or more of the features described herein, the current shaping section of the first planar current conductor may have a thickness that is no greater than twice a skin depth of the AC current at not less than one-half of the predetermined maximum frequency.

In addition to one or more of the features described herein, the current shaping section of the first planar current conductor may have a thickness that is no greater than twice a skin depth of the AC current at not less than the predetermined maximum frequency.

In addition to one or more of the features described herein, each leg may be defined by a respective first conductor edge and a respective second conductor edge, wherein all first conductor edges and second conductor edges run parallel to each other and are angled between 0 and 45 degrees relative to an orientation perpendicular to the first orientation and the second orientation.

In addition to one or more of the features described herein, each leg may be defined by a respective first conductor edge and a respective second conductor edge, wherein the first conductor edges run parallel to each other defining the slot and may be aligned perpendicular to the first orientation and the second orientation, the second conductor edges edge making an angle therebetween of between 0 and 90 degrees that is bisected by a centerline running through the slot perpendicular to the first orientation and the second orientation.

In another exemplary embodiment, a current sensing apparatus may include a first planar current conductor, a current shaping section of the first planar current conductor including a pair of parallel adjacent legs separated by a slot, the current shaping section being intermediate a first terminal section oriented in a first orientation and a second terminal section oriented in a second orientation perpendicular to the first orientation, wherein the first orientation of first terminal section is perpendicular to the pair of parallel adjacent legs and the slot of the current shaping section, a differential current sensor positioned over the pair of parallel adjacent legs of the current shaping section.

In addition to one or more of the features described herein, the current sensing apparatus may include a second planar current conductor, the first and second planar current conductors being coplanar and adjacent such that the first orientations of each respective first terminal section are parallel to each other and the second orientations of each respective second terminal section are parallel to each other, wherein the first terminal sections are separated by a distance L and the second terminal sections are separated by a distance T that is greater than the distance L.

In addition to one or more of the features described herein, each parallel adjacent leg may be defined by a respective first conductor edge and a respective second conductor edge, wherein the first conductor edges run parallel to each other defining the slot, wherein at least one of the respective second conductor edges is in contact with a thermally conductive electrical insulator.

In addition to one or more of the features described herein, each leg may be defined by a respective first conductor edge and a respective second conductor edge, wherein the first conductor edges define the slot, wherein all first conductor edges and second conductor edges run parallel to each other and to a line that bisects an angle between the first orientation and the second orientation.

In yet another exemplary embodiment, a current sensing apparatus may include a three-phase power inverter, a three-phase electric machine, first, second and third planar current conductors coupled between the three-phase power inverter and the three-phase electric machine, each planar current conductor including a current shaping section having a pair of parallel adjacent legs separated by a slot, the current shaping section being intermediate a first terminal section oriented in a first orientation and a second terminal section oriented in a second orientation perpendicular to the first orientation, wherein the first orientation of first terminal section is perpendicular to the pair of parallel adjacent legs and the slot of the current shaping section, each parallel adjacent leg being defined by a respective first conductor edge and a respective second conductor edge, wherein the first conductor edges respective to each current shaping section run parallel to each other defining the respective slot, wherein at least one of the second conductor edges is in contact with a thermally conductive electrical insulator, the planar current conductors being coplanar and arranged in spaced adjacency such that the first orientations of each respective first terminal section are parallel to each other and the second orientations of each respective second terminal section are parallel to each other, wherein adjacent first terminal sections are separated by a distance L and adjacent second terminal sections are separated by a distance T that is greater than the distance L, and a respective differential current sensor positioned over each pair of parallel adjacent legs of each current shaping section.

The above features and advantages, and other features and advantages of the disclosure are readily apparent from the following detailed description when taken in connection with the accompanying drawings.

### BRIEF DESCRIPTION OF THE DRAWINGS

Other features, advantages and details appear, by way of example only, in the following detailed description, the detailed description referring to the drawings in which:

FIG. 1 schematically illustrates current sensing apparatus, in accordance with one or more embodiments;

FIG. 2 illustrates a view of the current sensing apparatus of FIG. 1, in accordance with one or more embodiments;

FIG. 3 illustrates a current sensing apparatus, in accordance with one or more embodiments;

FIG. 4 illustrates a current sensing apparatus, in accordance with one or more embodiments;

FIG. 5 illustrates a current sensing apparatus, in accordance with one or more embodiments;

FIG. 6 illustrates a current sensing apparatus, in accordance with one or more embodiments;

FIG. 7 illustrates a current sensing apparatus, in accordance with one or more embodiments; and

FIG. 8 illustrates multiple current sensing apparatus, in accordance with one or more embodiments, in accordance with one or more embodiments.

### DETAILED DESCRIPTION

The following description is merely exemplary in nature and is not intended to limit the present disclosure, its application or uses. Throughout the drawings, corresponding reference numerals indicate like or corresponding parts and features.

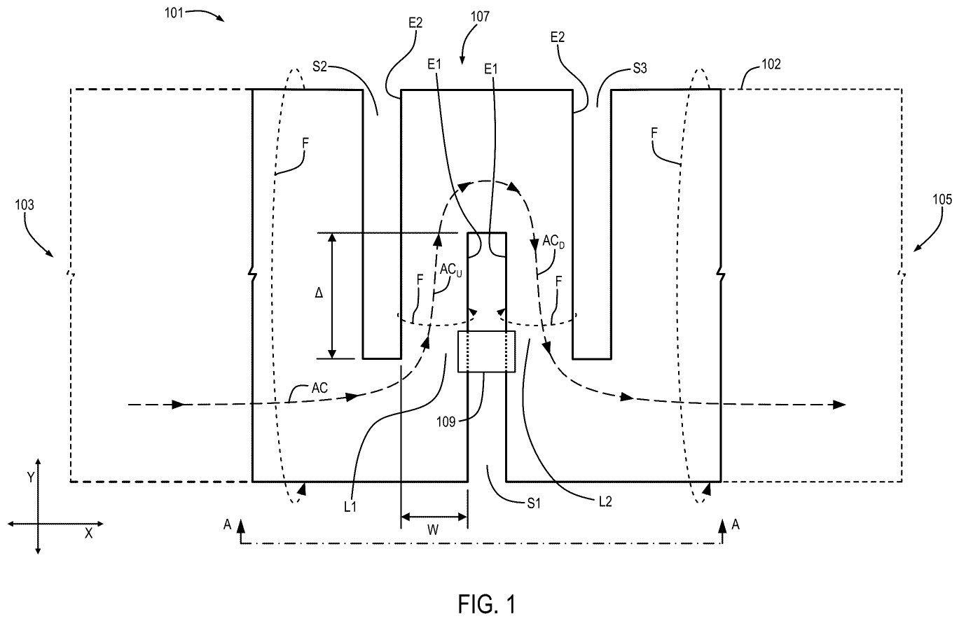

FIG. 1 schematically illustrates a current sensing apparatus 101 including a planar current conductor 102 such as a substantially flat bus bar fabricated from a conductive material such as copper, brass or aluminum, for example. The planar current conductor 102 may be used as a low impedance electrical coupling for alternating current (AC) currents such as between one phase leg of a three-phase power inverter and one phase winding of an electric machine. The planar current conductor 102 may have a first terminal section 103 and a second terminal section 105. The first terminal section 103 has a first orientation and the second terminal section 105 has a second orientation. In the embodiment of FIG. 1, both the first orientation and the second orientation are the same orientation X. The planar current conductor 102 may include a current shaping section 107 intermediate the first terminal section 103 and a second terminal section 105. The current shaping section 107 may have a pair of adjacent legs L1 and L2 separated by a slot S1. Each leg L1 and L2 may be defined by a first conductor edge E1 and a second conductor edge E2. The first conductor edges E1 run parallel to each other and are aligned perpendicular to the orientation X of the first terminal section 103 and the second terminal section 105. Thus, the slot S1 is defined by first edges E1 and runs in an orientation Y perpendicular to the orientation X of first terminal section 103 and the second terminal section 105. In the embodiment of FIG. 1, the second conductor edges E2 are also parallel to the first conductor edges E1, thus defining each leg L1 and L2 having parallel limits between the respective defining edges E1 and E2. In the embodiment of FIG. 1, the second conductor edges E2 define one side of respective slots S2 and S3. In the various figures herein, slots are shown with exaggerated dimensions relative to the width of the legs.

In conductive operation, AC current may flow between the first terminal section 103 and a second terminal section 105 through the current shaping section 107 generally as shown by the path labeled AC. The instantaneous AC current through leg L1 flows with first directional components AC_{U} upward in FIG. 1, around the slot S1 and with second directional components AC_{D} downward in FIG. 1. Directional components AC_{U} and AC_{D} are opposite to each other but parallel. Thus, it is appreciated that the AC current through the first terminal section 103 and a second terminal section 105 is oriented in the corresponding orientation X and the current AC through the legs L1 and L2 of the current shaping section 107 is oriented in the corresponding orientation Y. Magnetic field orientations corresponding to the AC current through the first terminal section 103, the second terminal section 105, and the legs L1 and L2 of the current shaping section 107 are generally labeled F in FIG. 1. A differential current sensor 109 may be positioned over the legs L1 and L2 of the current shaping section 107 for isolated measuring of current through the planar current conductor 102. A differential current sensor 109 is only illustrated in the embodiment of FIG. 1 and not otherwise illustrated in the other embodiments herein merely for clarity in the drawings, it being understood that all embodiments herein may include a differential current sensor as described with respect to FIG. 1. Such differential current sensors may relate the strength of a magnetic field within defined regions of the sensor corresponding to defined regions of the legs L1 and L2 of the current shaping section. Such differential current sensors may be sensitive to the magnetic fields oriented perpendicular to a proximate current of interest and least sensitive to the magnetic fields oriented parallel to the proximate current of interest. Thus, in the embodiment of FIG. 1 for example, a differential current sensor 109 is not substantially influenced by magnetic fields associated with the flow of AC currents through the first terminal section 103 and a second terminal section 105, which magnetic fields are oriented parallel to the proximate current of interest. Such differential current sensors 109 may be commonly referred to as point field detectors (PFD) and may rely on various technologies such as magneto-resistance (MR) sensors, hall effect sensors, giant magneto-resistance (GMR) sensors, tunnel magneto-resistance (TMR) sensors. In systems wherein the fundamental frequency of the AC current flowing through the planar current conductor 102 is substantial, such as propulsion motor systems in electrified vehicle powertrains, skin effects may skew current distribution (i.e., current accumulation) toward edges and corners of current conductors as frequency increases, thus affecting magnetic field density locally in the same fashion. This phenomenon may result in unacceptable sensor error and non-linearities within the desired operating bandwidth (i.e., the fundamental frequency of the AC current flowing through the planar current conductor 102). In exemplary propulsion motor systems in electrified vehicle powertrains for example, the fundamental frequency may span three orders of magnitude, for example from near zero low single digit Hz to 1-2 kHz at a maximum bandwidth frequency corresponding to 18000-36000 rpm in some motors. In any given system, the fundamental AC frequency may have a predetermine maximum frequency. Even higher maximum fundamental AC frequencies of 10 kHz and more may be achievable with emerging high-speed machines and solid-state switching technologies such as silicon carbide (SiC) MOSFETs, gallium nitride (GaN) transistors, diamond MOSFETs, carbon nano-tube transistors, and graphene-based transistors.

The skin effect is a phenomenon whereby AC current does not flow uniformly with respect to the cross-section of a conductor. The current density is highest near the surface of the conductor and decreases exponentially as distance from the surface increases. Skin depth refers to the point at which the current density reaches approximately 37% of its value at the surface of the conductor. Thus, approximately 63% of a conductor's total current is carried above one skin depth. At two skin depths, the current density reaches approximately 5% of its value at the surface of the conductor. Thus, approximately 95% of a conductor's total current is carried above two skin depths. Calculating skin depth requires the frequency of the AC current and the resistivity and relative permeability of the conductor material and may be approximated as follows.

$$δ = \sqrt{\frac{ρ}{π f μ}} \qquad [ 1 ]$$

wherein δ is the skin depth;
   π is the ratio of the circumference of a circle to the circle diameter;
   ρ is the resistivity of the conductor;
   f is the frequency of the AC current; and
   μ is the permeability of the conductor.

An exemplary conductor fabricated from copper may have a skin depth of approximately 2.1 mm at 1 KHz (1.5 mm at 2 kHz). An exemplary conductor fabricated from aluminum may have a skin depth of approximately 2.6 mm at 1 KHz (1.8 at 2 kHz). An exemplary conductor fabricated from brass (70/30) may have a skin depth of approximately 3.9 mm at 1 KHz (2.8 at 2 kHz).

Current density spread across the expected spectrum of the fundamental AC frequency, and hence local magnetic field density spread, may be reduced in the local conductor regions seen by the differential current sensor 109 by dimensional reductions in the current shaping section 107 of the planar current conductor 102. Legs L1 and L2 of the current shaping section 107 may have width W as shown in FIG. 1. In an embodiment, the AC current may vary up to a predetermined maximum fundamental frequency which may be a system rating or a design limit determined as a performance metric, a system physical limitation, or motor AC frequency limit. Regardless, the system may have a predetermined maximum fundamental frequency of the AC current. Advantageously, the width W of each leg L1 and L2 may be established as no greater than some multiple of skin depth at an AC frequency related to the maximum fundamental frequency of the AC current. In an embodiment, the width W may be no greater than twice the skin depth at not less than one-half the predetermined maximum fundamental frequency of the AC current. In another embodiment, the width W may be no greater than twice the skin depth at the predetermined maximum fundamental frequency of the AC current.

Legs L1 and L2 of the current shaping section 107 may have an overlap A of the first conductor edge E1 and the second conductor edge E2 as shown in FIG. 1. Larger overlaps are generally advantageous in directing the current components parallel to the orientation Y resulting in higher fidelity in the output of the differential current sensor 109. The overlap A of the first conductor edge E1 and the second conductor edge E2 may be established as no less than some multiple of skin depth at an AC frequency related to the maximum fundamental frequency of the AC current. In an embodiment, the overlap A may be no less than twice the skin depth at not less than one-half the predetermined maximum fundamental frequency of the AC current. In another embodiment, the overlap A may be no less than twice the skin depth at the predetermined maximum fundamental frequency of the AC current.

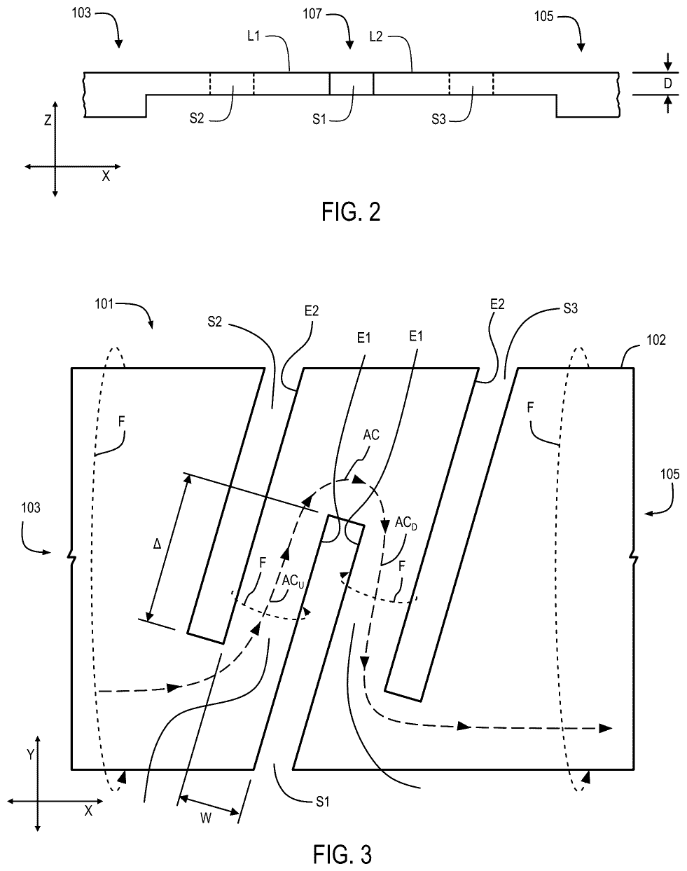

The current shaping section 107, and more particularly in some embodiments, the Legs L1 and L2 may have a thickness D in an orientation Z (normal to the plane of the planar current conductor 102) and as illustrated in FIG. 2 taken in the indicated direction of line A-A in FIG. 1. As shown in FIG. 2, the current shaping section 107 may be a thinned out section between thicker first terminal section 103 and second terminal section 105. Alternatively, the entire planar current conductor 102 may have thickness D. The thickness D of the current shaping section 107 may be established as no greater than some multiple of skin depth at an AC frequency related to the maximum fundamental frequency of the AC current. In an embodiment, the thickness D may be no greater than twice the skin depth at not less than one-half the predetermined maximum fundamental frequency of the AC current. In another embodiment, the thickness D may be no greater than twice the skin depth at the predetermined maximum fundamental frequency of the AC current.

FIG. 3 schematically illustrates an embodiment of a current sensing apparatus 101 including a planar current conductor 102 such as a substantially flat bus bar. In the embodiment of FIG. 3, each leg L1 and L2 is defined by a respective first conductor edge E1 and a respective second conductor edge E2. All first conductor edges E1 and second conductor edges E2 run parallel to each other and may be angled between 0 and 45 degrees relative to an orientation Y perpendicular to the common orientation X of the first terminal section 103 and a second terminal section 105.

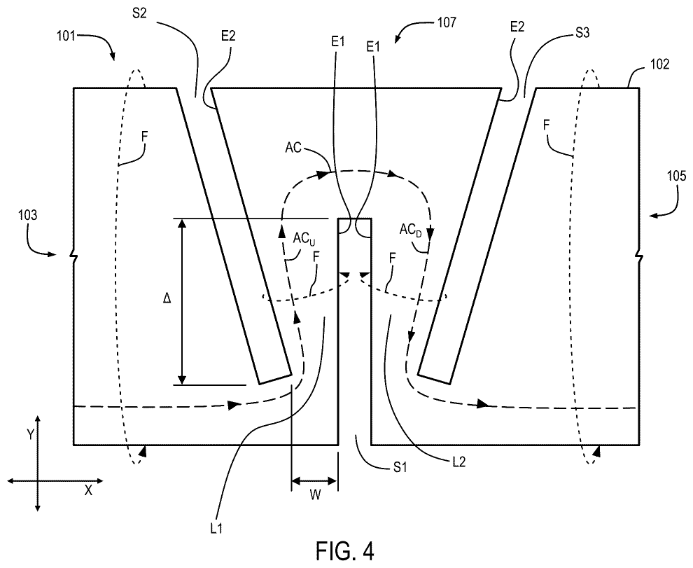

FIG. 4 schematically illustrates an embodiment of a current sensing apparatus 101 including a planar current conductor 102 such as a substantially flat bus bar. In the embodiment of FIG. 4, each leg L1 and L2 is defined by a respective first conductor edge E1 and a respective second conductor edge E2. The first conductor edges E1 run parallel to each other defining the slot S1 and are aligned perpendicular to the common orientation X of the first terminal section 103 and a second terminal section 105. The second conductor edges E2 make an angle therebetween of between 0 and 90 degrees that is bisected by a centerline running through the slot S1 perpendicular to the common orientation X of the first terminal section 103 and a second terminal section 105.

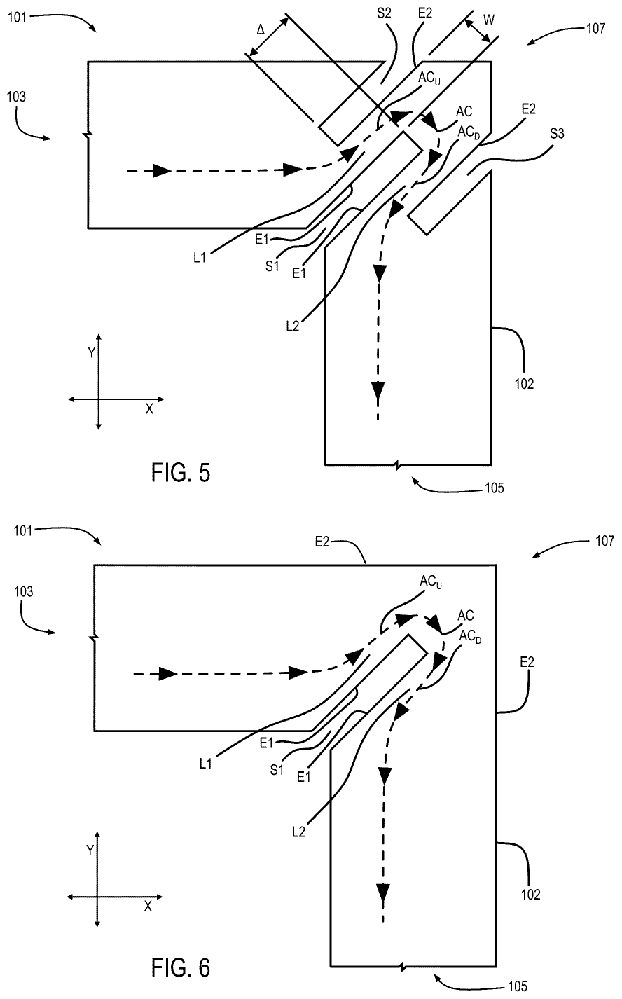

FIG. 5 schematically illustrates an embodiment of a current sensing apparatus 101 including a planar current conductor 102 such as a substantially flat bus bar. Bus bars may be used to couple power inverters to electric motors. In highly integrated applications such as automotive usage, bus bars may include shapes other than straight runs. For example, bus bars may make 90 degree in-plane bends between the power inverter switches and other terminal points such as output terminals of the power inverter. Advantageously, embodiments of FIGS. 5-8 may be utilized with such bus bar arrangements wherein current shaping sections may be located at the directional change of the bus bar. In the embodiment of FIG. 5, the planar current conductor 102 may have a first terminal section 103 and a second terminal section 105. The first terminal section 103 has a first orientation and the second terminal section 105 has a second orientation. In the embodiment of FIG. 5, the first orientation is an orientation X and the second orientation is an orientation Y wherein orientation X and orientation Y are perpendicular. The planar current conductor 102 may include a current shaping section 107 intermediate the first terminal section 103 and a second terminal section 105. The current shaping section 107 may have a pair of adjacent legs L1 and L2 separated by a slot S1. Each leg L1 and L2 may be defined by a first conductor edge E1 and a second conductor edge E2. The first conductor edges E1 run parallel to each other and are aligned with a line that bisects the angle made by the first orientation X of the first terminal section 103 and the second orientation Y of the second terminal section 105. Thus, the slot S1 is defined by first edges E1 and runs along the line that bisects the angle made by the first orientation X of the first terminal section 103 and the second orientation Y of the second terminal section 105. In the embodiment of FIG. 5, the second conductor edges E2 are also parallel to the first conductor edges E1, thus defining each leg L1 and L2 having parallel limits between the respective defining edges E1 and E2. In the embodiment of FIG. 5, the second conductor edges E2 define one side of respective slots S2 and S3 which run parallel to slot S1.

FIG. 6 schematically illustrates an embodiment of a current sensing apparatus 101 including a planar current conductor 102 such as a substantially flat bus bar. In the embodiment of FIG. 6, the planar current conductor 102 may have a first terminal section 103 and a second terminal section 105. The first terminal section 103 has a first orientation and the second terminal section 105 has a second orientation. In the embodiment of FIG. 6, the first orientation is an orientation X and the second orientation is an orientation Y wherein orientation X and orientation Y are perpendicular. The planar current conductor 102 may include a current shaping section 107 intermediate the first terminal section 103 and a second terminal section 105. The current shaping section 107 may have a pair of adjacent legs L1 and L2 separated by a slot S1. Each leg L1 and L2 may be defined by a first conductor edge E1 and a second conductor edge E2. The first conductor edges E1 run parallel to each other and are aligned with a line that bisects the angle made by the first orientation X of the first terminal section 103 and the second orientation Y of the second terminal section 105. Thus, the slot S1 is defined by first edges E1 and runs along the line that bisects the angle made by the first orientation X of the first terminal section 103 and the second orientation Y of the second terminal section 105. In the embodiment of FIG. 6, the second conductor edges E2 run parallel to respective first terminal sections 103 and respective second terminal sections 105.

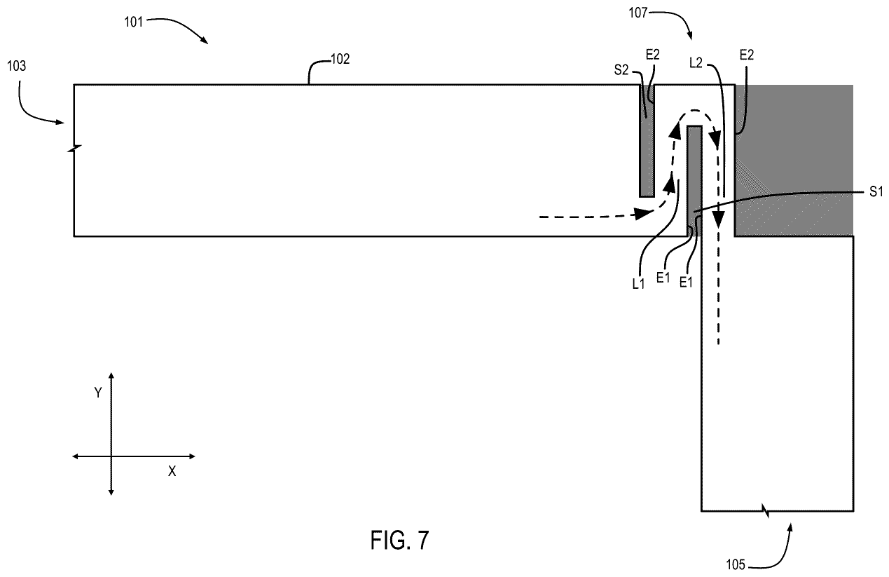

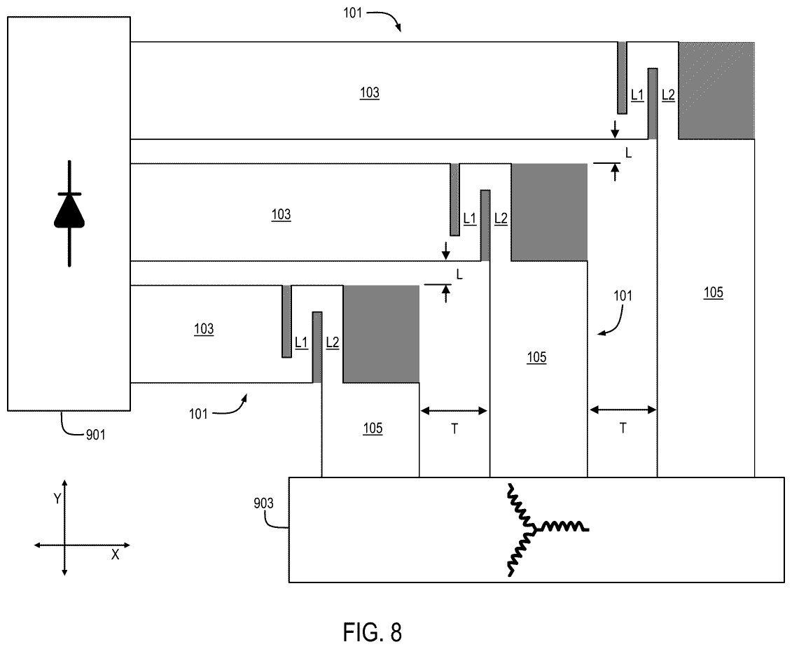

FIG. 7 schematically illustrates an embodiment of a current sensing apparatus 102 including a planar current conductor 102 such as a substantially flat bus bar. In the embodiment of FIG. 7, the planar current conductor 102 may have a first terminal section 103 and a second terminal section 105. The first terminal section 103 has a first orientation and the second terminal section 105 has a second orientation. In the embodiment of FIG. 7, the first orientation is an orientation X and the second orientation is an orientation Y wherein orientation X and orientation Y are perpendicular. The planar current conductor 102 may include a current shaping section 107 intermediate the first terminal section 103 and a second terminal section 105. The current shaping section 107 may have a pair of adjacent legs L1 and L2 separated by a slot S1. Each leg L1 and L2 may be defined by a first conductor edge E1 and a second conductor edge E2. The first conductor edges E1 run parallel to each other and are aligned perpendicular to the first orientation X of the first terminal section 103. Thus, the slot S1 is defined by first edges E1 and runs perpendicular to the first orientation X of the first terminal section 103. In the embodiment of FIG. 7, the second conductor edges E2 are also parallel to the first conductor edges E1, thus defining each leg L1 and L2 having parallel limits between the respective defining edges E1 and E2. In the embodiment of FIG. 7, one second conductor edge E2 defines one side of respective slot S2 which runs parallel to slot S1. In the busbar areas eliminated due to slots and cuts, polymer material can be added as filler to provide mechanical strength and thermal pathways with high electrical insulation. Polymer fill is shown in FIGS. 7 and 8 as shaded regions; however, it is understood that such polymers may be added in all embodiments described herein.

FIG. 8 schematically illustrates an embodiment of a three current sensing apparatus 101 as described herein with respect to FIG. 7. In the embodiment of FIG. 8, the current sensing apparatus 101 may be coplanar and arranged in spaced adjacency such that the first orientations X of each respective first terminal section 103 are parallel to each other and the second orientations Y of each respective second terminal section 105 are parallel to each other. The adjacent first terminal sections 103 are separated by a distance L and the adjacent second terminal sections are separated by a distance T that is greater than the distance L. Close spacing of the current sensing apparatus may be advantageous in applications where packaging space efficiency is important, such as propulsion motor systems in electrified vehicle powertrains. Since the magnetic fields corresponding to the first terminal sections 103 do not couple to the differential current sensors 109 due to the perpendicular relationship between the orientation X of the first terminal sections 103 and the orientation Y of the legs L1 and L2 of the current shaping sections 107, the first terminal sections 103 may be closely spaced by a distance L. However, since the magnetic fields corresponding to the second terminal sections 105 may couple to the differential current sensors 109 due to the parallel relationship between the orientation Y of the second terminal sections 105 and the orientation Y of the legs L1 and L2 of the current shaping sections 107, the second terminal sections 105 may be further spaced by a distance T that is greater than the distance L. In the embodiment of FIG. 8, the first terminal sections 103 may be coupled to a power inverter 901 and the second terminal sections 105 may be coupled to phase windings 903 of a propulsion motor.

The terminology used herein is for the purpose of describing particular embodiments only and is not intended to be limiting. The terms “a” and “an” do not denote a limitation of quantity, but rather denote the presence of at least one of the referenced items. The term “or” means “and/or” unless clearly indicated otherwise by context. Reference throughout the specification to “an aspect”, means that a particular element (e.g., feature, structure, step, or characteristic) described in connection with the aspect is included in at least one aspect described herein, and may or may not be present in other aspects. In addition, it is to be understood that the described elements may be combined in any suitable manner in the various aspects.

All numeric values herein are assumed to be modified by the term “about” whether or not explicitly indicated. For the purposes of the present disclosure, ranges may be expressed as from “about” one particular value to “about” another particular value. The term “about” generally refers to a range of numeric values that one of skill in the art would consider equivalent to the recited numeric value, having the same function or result, or reasonably within manufacturing tolerances of the recited numeric value generally. Similarly, numeric values set forth herein are by way of non-limiting example and may be nominal values, it being understood that actual values may vary from nominal values in accordance with environment, design and manufacturing tolerance, age and other factors.

When an element such as a layer, film, region, or substrate is referred to as being “on” another element, it can be directly on the other element or intervening elements may also be present. In contrast, when an element is referred to as being “directly on” another element, there are no intervening elements present. Therefore, unless explicitly described as being “direct,” when a relationship between first and second elements is described in the above disclosure, that relationship may be a direct relationship where no other intervening elements are present between the first and second elements but may also be an indirect relationship where one or more intervening elements are present (either spatially or functionally) between the first and second elements.

One or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Unless defined otherwise, technical and scientific terms used herein have the same meaning as is commonly understood by one of skill in the art to which this disclosure belongs.

Unless specified to the contrary herein, all test standards are the most recent standard in effect as of the filing date of this application, or, if priority is claimed, the filing date of the earliest priority application in which the test standard appears.

While the above disclosure has been described with reference to exemplary embodiments, it will be understood by those skilled in the art that various changes may be made and equivalents may be substituted for elements thereof without departing from its scope. In addition, many modifications may be made to adapt a particular situation or material to the teachings of the disclosure without departing from the essential scope thereof. Therefore, it is intended that the present disclosure not be limited to the particular embodiments disclosed, but will include all embodiments falling within the scope thereof.

What is claimed is:

1. A current sensing apparatus, comprising:
a first planar current conductor carrying an alternating current (AC) current that is variable up to a predetermined maximum frequency;
a current shaping section of the first planar current conductor including a pair of adjacent legs separated by a slot, the current shaping section configured to shape the AC current to flow around the slot such that the AC current has parallel directional components running parallel to the slot on opposite sides of the slot that are in opposite directions;
each leg having width that is no greater than twice a skin depth of the AC current at not less than one-half of the predetermined maximum frequency; and
a differential current sensor sensing the parallel directional components of the AC current on opposite sides of the slot.

2. The apparatus of claim 1, wherein each leg has width that is no greater than twice the skin depth of the AC current at not less than the predetermined maximum frequency.

3. The apparatus of claim 1, wherein each leg is defined by a respective first conductor edge and a respective second conductor edge, the first conductor edge and the second conductor edge of each leg overlapping by no less than twice the skin depth of the AC current at not less than one-half of the predetermined maximum frequency.

4. The apparatus of claim 2, wherein each leg is defined by a respective first conductor edge and a respective second conductor edge, the first conductor edge and the second conductor edge of each leg overlapping by no less than twice the skin depth of the AC current at the predetermined maximum frequency.

5. The apparatus of claim 2, wherein each leg is defined by a respective first conductor edge and a respective second conductor edge, the first conductor edge and the second conductor edge of each leg overlapping by no less than twice the skin depth of the AC current at not less than one-half of the predetermined maximum frequency.

6. The apparatus of claim 1, wherein the current shaping section is intermediate a first terminal section and a second terminal section, the first terminal section being oriented in a first orientation and the second terminal section being oriented in a second orientation.

7. The apparatus of claim 6, wherein the first orientation and the second orientation are the same.

8. The apparatus of claim 6, wherein the first orientation and the second orientation are perpendicular.

9. The apparatus of claim 8, wherein the first orientation of the first terminal section is perpendicular to the parallel directional components of the AC current on opposite sides of the slot of the current shaping section.

10. The apparatus of claim 8, further comprising a second planar current conductor as set forth in claim 8, wherein the first orientations of each respective first terminal section are perpendicular to the parallel directional components of the AC current on opposite sides of the slots of the respective current shaping sections, the first and second planar current conductors being coplanar and adjacent such that the first orientations of each respective first terminal section are parallel to each other and the second orientations of each respective second terminal section are parallel to each other, wherein the first terminal sections are separated by a distance L and the second terminal sections are separated by a distance T that is greater than the distance L.

11. The apparatus of claim 6, wherein each leg is defined by a respective first conductor edge and a respective second conductor edge, wherein at least one of the respective first conductor edges and second conductor edges is in contact with a thermally conductive electrical insulator.

12. The apparatus of claim 1, wherein the current shaping section of the first planar current conductor has a thickness that is no greater than twice a skin depth of the AC current at not less than one-half of the predetermined maximum frequency.

13. The apparatus of claim 1, wherein the current shaping section of the first planar current conductor has a thickness that is no greater than twice a skin depth of the AC current at not less than the predetermined maximum frequency.

14. The apparatus of claim 7, wherein each leg is defined by a respective first conductor edge and a respective second conductor edge, wherein all first conductor edges and second conductor edges run parallel to each other and are angled between 0 and 45 degrees relative to an orientation perpendicular to the first orientation and the second orientation.

15. The apparatus of claim 7, wherein each leg is defined by a respective first conductor edge and a respective second conductor edge, wherein the first conductor edges run parallel to each other defining the slot and are aligned perpendicular to the first orientation and the second orientation, the second conductor edges edge making an angle therebetween of between 0 and 90 degrees that is bisected by a centerline running through the slot perpendicular to the first orientation and the second orientation.

16. A current sensing apparatus, comprising:
a first planar current conductor;
a current shaping section of the first planar current conductor including a pair of parallel adjacent legs separated by a slot, the current shaping section being intermediate a first terminal section oriented in a first orientation and a second terminal section oriented in a second orientation perpendicular to the first orientation, wherein the first orientation of first terminal section is perpendicular to the pair of parallel adjacent legs and the slot of the current shaping section; and
a differential current sensor positioned over the pair of parallel adjacent legs of the current shaping section.

17. The apparatus of claim 16, further comprising a second planar current conductor as set forth in claim 16, the first and second planar current conductors being coplanar and adjacent such that the first orientations of each respective first terminal section are parallel to each other and the second orientations of each respective second terminal section are parallel to each other, wherein the first terminal sections are separated by a distance L and the second terminal sections are separated by a distance T that is greater than the distance L.

18. The apparatus of claim 16, wherein each parallel adjacent leg is defined by a respective first conductor edge and a respective second conductor edge, wherein the first conductor edges run parallel to each other defining the slot, wherein at least one of the respective second conductor edges is in contact with a thermally conductive electrical insulator.

19. The apparatus of claim 16, wherein each leg is defined by a respective first conductor edge and a respective second conductor edge, wherein the first conductor edges define the slot, wherein all first conductor edges and second conductor edges run parallel to each other and to a line that bisects an angle between the first orientation and the second orientation.

20. A current sensing apparatus, comprising:
a three-phase power inverter;
a three-phase electric machine;
first, second and third planar current conductors coupled between the three-phase power inverter and the three-phase electric machine;
each planar current conductor including a current shaping section having a pair of parallel adjacent legs separated by a slot, the current shaping section being intermediate a first terminal section oriented in a first orientation and a second terminal section oriented in a second orientation perpendicular to the first orientation, wherein the first orientation of first terminal section is perpendicular to the pair of parallel adjacent legs and the slot of the current shaping section;
each parallel adjacent leg being defined by a respective first conductor edge and a respective second conductor edge, wherein the first conductor edges respective to each current shaping section run parallel to each other defining the respective slot, wherein at least one of the second conductor edges is in contact with a thermally conductive electrical insulator;
the planar current conductors being coplanar and arranged in spaced adjacency such that the first orientations of each respective first terminal section are parallel to each other and the second orientations of each respective second terminal section are parallel to each other, wherein adjacent first terminal sections are separated by a distance L and adjacent second terminal sections are separated by a distance T that is greater than the distance L; and
a respective differential current sensor positioned over each pair of parallel adjacent legs of each current shaping section.
